(19) United States
(12) Patent Application Publication
(10) Pub. No.: US 2025/0028011 A1
(43) Pub. Date: Jan. 23, 2025

(54) CHARGING STATION HEALTH MONITORING DEVICE AND METHOD

(71) Applicant: TE Connectivity Solutions GmbH, Schaffhausen (CH)

(72) Inventors: Ram Kishore Venkatesan, Winston Salem, NC (US); Dinesh Loku Hemnani, Greensboro, NC (US); Paul T. Angell, Winston Salem, NC (US); Nathan Philip Myer, Lancaster, PA (US)

(21) Appl. No.: 18/356,269

(22) Filed: Jul. 21, 2023

(51) Int. Cl. G01R 31/69; G01R 1/067; G01R 27/02

(52) U.S. Cl. CPC G01R 31/69; G01R 1/067; G01R 27/02; B60L 53/16

(57) ABSTRACT

A charging station health monitoring device for monitoring a health of a charging socket of a charging station includes a device housing having a user interface. The charging station health monitoring device includes a control panel in the device housing. The control panel operably coupled to the user interface. The charging station health monitoring device includes a testing sensor coupled to the control panel. The testing sensor coupled to the control panel. The testing sensor includes a testing pin, a testing probe, and an insulator between the testing pin and the testing probe. The testing pin includes a pin interface. The testing probe includes a probe interface. The probe interface spaced apart from the pin interface. The testing sensor is configured to be plugged into the charging socket such that the pin interface and the probe interface are configured to engage the charging socket at different testing locations to determine a resistance measurement for the charging socket.

### BACKGROUND OF THE INVENTION

The subject matter herein relates generally to charging stations for electric vehicles.

Charging stations are used to charge electric vehicles. The charging stations use a charging plug, which connects to a charging inlet of the vehicle, to charge the electric vehicle. The charging plug includes charging sockets, which plug into the charging inlet, to mate with the charging pins of the charging inlet. With fast charging, the charging station provides high current charging. The temperatures of the charging sockets and the charging pins increase during high current charging. The charging sockets and the charging pins may become damaged due to overheating during high current charging. The charging plugs may become worn over time due to use, exposure to elements (for example, moisture and debris), and lack of maintenance. There is a need for maintenance testing of the charging sockets of the charging plug.

### BRIEF DESCRIPTION OF THE INVENTION

In one embodiment, a charging station health monitoring device for monitoring a health of a charging socket of a charging station is provided. The charging station health monitoring device includes a device housing having a user interface. The charging station health monitoring device includes a control panel in the device housing. The control panel operably coupled to the user interface. The charging station health monitoring device includes a testing sensor coupled to the control panel. The testing sensor coupled to the control panel. The testing sensor includes a testing pin, a testing probe, and an insulator between the testing pin and the testing probe. The testing pin includes a pin interface. The testing probe includes a probe interface. The probe interface spaced apart from the pin interface. The testing sensor is configured to be plugged into the charging socket such that the pin interface and the probe interface are configured to engage the charging socket at different testing locations to determine a resistance measurement for the charging socket.

In another embodiment, a charging station health monitoring device for monitoring a health of a charging socket of a charging station is provided. The charging station health monitoring device includes a device housing having a user interface. The charging station health monitoring device includes a control panel in the device housing. The control panel operably coupled to the user interface. The charging station health monitoring device includes a testing sensor coupled to the control panel. The testing sensor coupled to the control panel. The testing sensor includes a four wire resistance probe configured to be plugged into the charging socket to interface with the charging socket at four points to determine a resistance measurement for the charging socket.

In a further embodiment, a method of monitoring health of a charging socket of a charging station is provided. The method provides providing a charging station health monitoring device includes a device housing having a user interface, a control panel in the device housing operably coupled to the user interface, and a testing sensor coupled to the control panel. The method plugs the testing sensor into the charging socket such that a pin interface of a testing pin of the testing sensor engages the charging socket at a first testing location and a probe interface of a testing probe of the testing socket engages the charging socket at a second testing location. The method determines a resistance measurement for the charging socket using the testing pin and the testing probe. The method provides an output at the user interface based on the resistance measurement indicative of the health of the charging socket.

### BRIEF DESCRIPTION OF THE DRAWINGS

FIG. 1 illustrates a charging station health monitoring device in accordance with an exemplary embodiment.

FIG. 2 illustrates the monitoring device in accordance with an exemplary embodiment.

FIG. 3 illustrates the monitoring device in accordance with an exemplary embodiment.

FIG. 4 is a cross-sectional view of the monitoring device testing the charging socket in accordance with an exemplary embodiment.

FIG. 5 is a perspective view of the testing sensor in accordance with an exemplary embodiment.

FIG. 6 illustrates the monitoring device in accordance with an exemplary embodiment.

FIG. 7 is a cross-sectional view of the monitoring device testing the charging socket in accordance with an exemplary embodiment.

FIG. 8 is a perspective view of the testing sensor shown in FIGS. 6 and 7 in accordance with an exemplary embodiment.

FIG. 9 is a schematic view of the monitoring device in accordance with an exemplary embodiment.

FIG. 10 is a schematic view of the monitoring device in accordance with an exemplary embodiment.

### DETAILED DESCRIPTION OF THE INVENTION

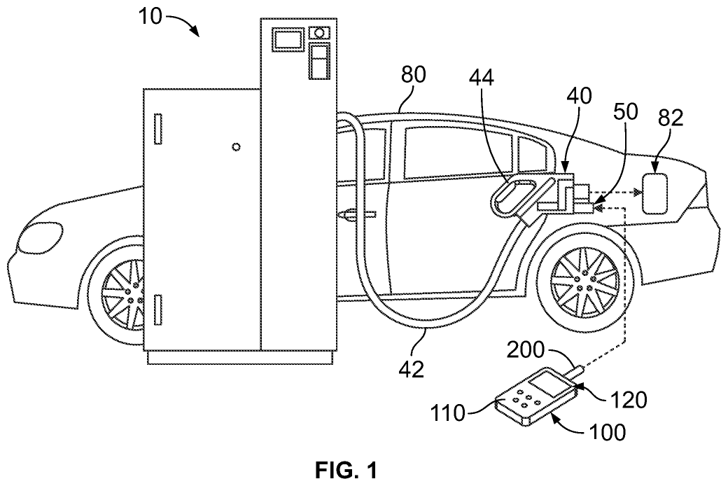

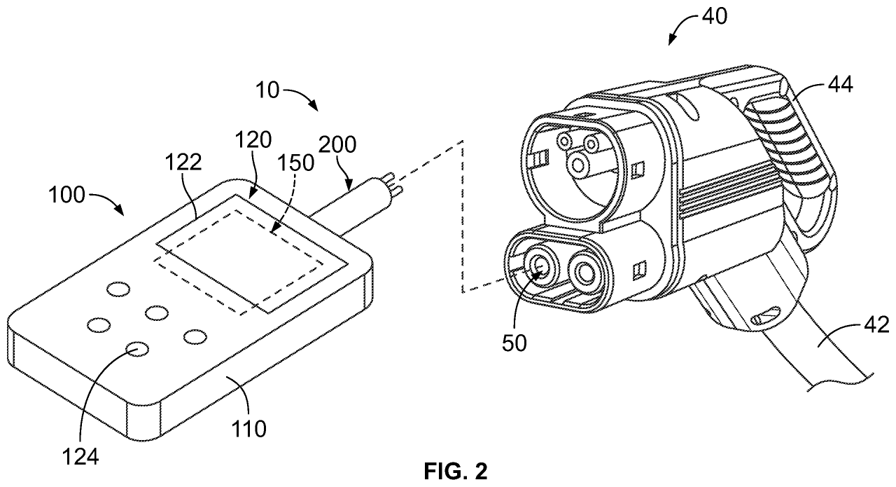

FIG. 1 illustrates a charging station health monitoring device 100 (referred to hereinafter as monitoring device 100) in accordance with an exemplary embodiment. FIG. 2 illustrates the monitoring device 100 in accordance with an exemplary embodiment. The monitoring device 100 is used for monitoring health of charging sockets 50 of a charging plug 40 of a charging station 10 (FIG. 1). In an exemplary embodiment, the monitoring device 100 is portable. For example, the monitoring device 100 may be a handheld unit. The monitoring device 100 enables individual consumers, fleet owners, charging station maintenance contractors, or other individuals to assess the health of the charging plug 40 and determine if any maintenance and/or replacement of the charging plug 40 or components thereof is required. The monitoring device 100 measures the resistance of the connection in the charging plug 40 to determine the health of the charging socket 50. In an exemplary embodiment, the monitoring device 100 compares the measured resistance with a known database of connections ranging from good to poor and provides the user with an indication of health of the particular charging socket to determine if the charging socket needs service or replacement. For example, the monitoring device 100 provides an output to the user indicative of the health of the charging socket 50.

The charging station 10 includes the charging plug 40 at the end of a charging cable 42. The charging station 10 supplies power to the charging plug 40, such as to charge an electric vehicle 80. The charging plug 40 may be a Level 1 charger, a Level 2 charger or a Level 3 charger. In an exemplary embodiment, the charging plug may be a DC fast charging plug. The charging plug 40 may be any type of electric vehicle charging interface having an arrangement of charging terminals, such as a combined charging system (CCS) having both AC charging terminals and DC charging terminals. The charging plug 40 includes a handle 44 holding the charging sockets 50. The charging sockets 50 are configured to be plugged into a charging inlet 82 of the electric vehicle 80. The charging sockets 50 are configured to receive charging terminals (for example, charging pins) of the charging inlet 82.

The monitoring device 100 includes a device housing 110 having a user interface 120. The device housing 110 may be a handheld device. In an exemplary embodiment, the user interface 120 includes a display 122. Optionally, the display 122 may be a touchscreen configured to receive inputs. In various embodiments, the user interface 120 includes user inputs 124, such as buttons, keys, and input pad, or other types of user inputs. The monitoring device 100 may be controlled based on inputs at the user inputs 124. For example, the monitoring device 100 may be turned on or off at the user inputs 124. The operating mode of the monitoring device 100 may be controlled or changed at the user inputs 124.

The monitoring device 100 includes a control panel 150 in the device housing 110. The control panel 150 is operably coupled to the user interface 120. The control panel 150 may receive inputs from the user interface 120. The control panel 150 may send outputs to the user interface 120.

In an exemplary embodiment, the monitoring device 100 includes a testing sensor 200 configured to be plugged into the charging socket 50 for testing the charging socket 50. The testing sensor 200 is plugged into the interior of the charging socket 50 and engages the conductive portion of the charging socket 50. The testing sensor 200 determines a resistance measurement for the charging socket 50 to detect a health of the charging socket 50. In an exemplary embodiment, the testing sensor 200 is coupled to the device housing 110. For example, the testing sensor 200 extends from the top or front of the device housing 110. However, in alternative embodiments, the testing sensor 200 may be coupled to the device housing 110 by a cable or wire.

The testing sensor 200 is operably coupled to the control panel 150. Signals from the testing sensor 200 are transmitted to the control panel 150. The signals may be processed by the control panel 150 to determine the health of the charging socket 50. For example, the control panel 150 may use the resistance measurements from the testing sensor 200 to determine the health of the charging socket 50. The control panel 150 may determine if the charging socket 50 passes or fails the health monitoring test, such as by comparing the measured resistance to a known database. For example, the control panel 150 may determine if the measured resistance is below or above a threshold resistance measurement. If the measured resistance is below the threshold resistance measurement, the control panel 150 may send a pass output for display on the display 122 of the user interface 120. If the measured resistance as above the threshold resistance measurement, the control panel 150 may send a fail outputs for display on the display 122 of the user interface 120.

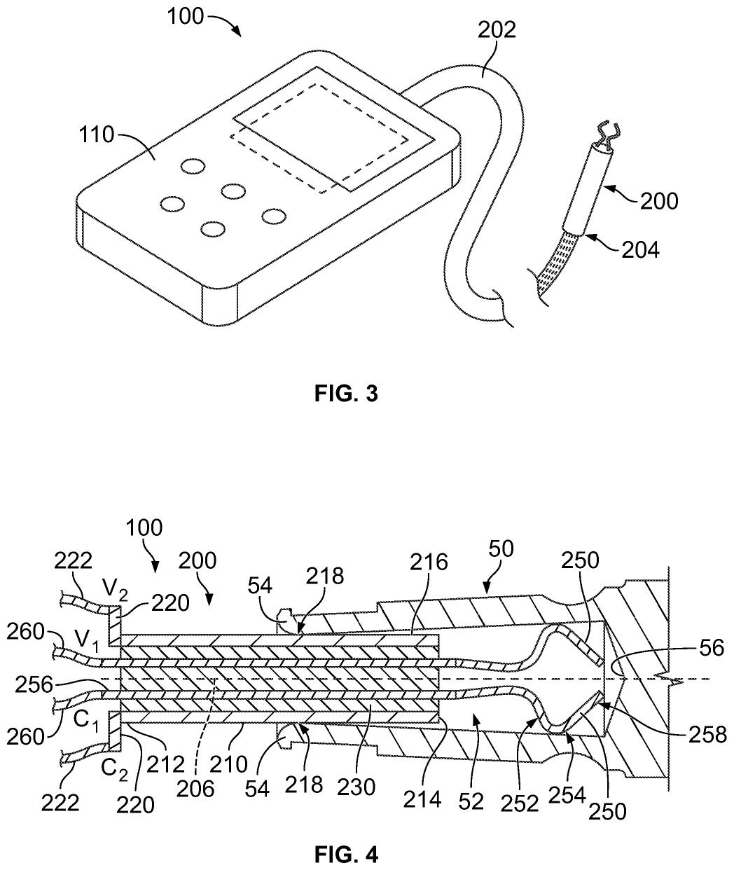

FIG. 3 illustrates the monitoring device 100 in accordance with an exemplary embodiment. FIG. 3 shows a testing cable 202 between the device housing 110 and the testing sensor 200. The testing sensor 200 is provided at an end 204 of the testing cable 202. The testing cable 202 allows manipulation or positioning of the testing sensor 200 relative to the device housing 110.

FIG. 4 is a cross-sectional view of the monitoring device 100 testing the charging socket 50 in accordance with an exemplary embodiment. During testing, the testing sensor 200 is plugged into a receptacle 52 of the charging socket 50. The testing sensor 200 engages the charging socket 50 at multiple locations to measure resistance of the charging socket 50 to monitor the health of the charging socket 50. In various embodiments, the exterior of the charging socket 50 may be covered by the charging plug such that the exterior of the charging socket 50 is inaccessible for testing by the monitoring device 100. Rather, the testing sensor 200 of the monitoring device 100 tests the charging socket 50 from inside the receptacle 52.

In various embodiments, the charging socket 50 is a tulip style charging socket having contact fingers 54 at the mating end of the charging socket 50. The contact fingers 54 are deflectable for mating engagement with the charging pin of the charging inlet of the electric vehicle. Optionally, the charging socket 50 may have a predetermined bore size in the receptacle 52 at the mating end. For example, the charging socket 50 may have an 8 mm diameter at the contact fingers 54. The receptacle 52 may be hollowed out to have a larger diameter at an inner end 56 of the receptacle 52. For example, the receptacle 52 may have the smallest diameter at the mating end (for example, at the contact fingers 54).

In an exemplary embodiment, the testing sensor 200 is a Kelvin resistance sensor (for example, a four wire resistance sensor) configured to determine a resistance measurement for the charging socket 50. The testing sensor 200 tests the charging socket 50 at different measurement points. For example, the measurement points may be axially and/or radially spaced apart from each other. In an exemplary embodiment, the testing sensor 200 includes a testing pin 210 and at least one testing probe 250. An insulator(s) 230 is located between the testing pin 210 and the at least one testing probe 250. In the illustrated embodiment, the testing sensor 200 includes a pair of the testing probes 250 (for example, a first testing probe and a second testing probe). The testing sensor 200 may include greater or fewer testing probes 250 in alternative embodiments.

The testing pin 210 extends between a first end 212 and a second end 214. In an exemplary embodiment, the testing pin 210 is hollow and receives the insulator 230 and testing probes 250 in the interior of the testing pin 210. The testing pin 210 is electrically conductive. For example, the testing pin 210 may be manufactured from a metal material, such as copper or aluminum. The testing pin 210 may be plated or coated, such as with a silver plating layer. The testing pin 210 includes an outer surface 216 defining a pin interface 218 configured to engage or interface with the charging socket 50. In an exemplary embodiment, the testing pin 210 is cylindrical and configured to plug in the mating end of the charging socket 50. The contact fingers 54 are configured to engage the testing pin 210 at the pin interface 218. Optionally, the pin interface 218 may extend circumferentially around the testing pin 210, such as at an intermediate location along the testing pin 210 between the first and second ends 212, 214. In various embodiments, the testing pin 210 is an 8 mm pin having a diameter of 8 mm.

In an exemplary embodiment, the testing pin 210 includes one or more tabs 220 extending from the testing pin 210. The tabs 220 are provided at the first end 212. Wires 222 are connected to the corresponding tabs 220. In the illustrated embodiment, two tabs 220 are provided. However, greater or fewer tabs 220 may be provided in alternative embodiments. The tabs 220 may be solder tabs or weld tabs configured to be soldered or welded to the wires 222. The wires 222 may be connected to the tabs 220 by other means in alternative embodiments. The other end of the wire 222 may be electrically connected to the control panel 150 (shown in FIG. 2).

In alternative embodiments, rather than having a cylindrical testing pin 210, the testing sensor 200 may include individual testing pins. For example, the testing pins may be parallel plates arranged at a predetermined spacing, such as approximately 8 mm spacing. The testing pins may include compliant portions, such as spring beams defining the pin interfaces 218 configured to interface with the charging socket 50 at different locations (for example, top and bottom of the testing sensor 200).

The testing probes 250 are located in the hollow interior of the testing pin 210. The insulator 230 electrically isolates the testing probes 250 from the testing pin 210. The testing probes 250 extend forward of the second end 214 of the testing pin 210. The testing probes 250 are configured to be plugged into the charging socket 50 to interface with the charging socket 50 at different locations from each other and different locations from the testing pin 210. In an exemplary embodiment, each testing probe 250 includes a deflectable spring finger 252 having a probe interface 254 configured to interface with the interior surface of the charging socket 50. The spring finger 252 is deflected inward when engaging the charging socket 50, creating an internal biasing force to maintain a reliable electrical connection between the spring finger 252 and the charging socket 50. In the illustrated embodiment, the testing sensor 200 includes two of the testing probes 250, such as an upper testing probe and a lower testing probe. The upper testing probe engages a top of the charging socket 50 and the lower testing probe engages the bottom of the charging socket 50. The testing probe 250 extends to a terminating end 256 opposite a mating end 258. A wire 260 is connected to the testing probe 250 at the terminating end 256. The wire 260 may be electrically connected to the control panel 150 (shown in FIG. 2).

In the illustrated embodiment, the testing pin 210 is configured to interface with the charging socket 50 at a first testing location, such as at the contact fingers 54. The testing probes 250 are configured to interface with the charging socket 50 and a second testing location axially offset from the first testing location. For example, the testing probes 250 may interface with the charging socket 50 proximate to the inner end 56 of the receptacle 52. Other testing locations are possible in alternative embodiments. In an exemplary embodiment, the pin interface 218 of the testing pin 210 is located a first distance from a central axis 206 of the testing sensor 200. The first distance may be a first radial distance of the testing pin 210 (for example, half the diameter of the testing pin 210, such as 4 mm). In an exemplary embodiment, the probe interface 254 of the testing probe 250 is located a second distance from the central axis 206. The second distance may be different than the first distance. For example, the second distance may be greater than the first distance. The testing probes 250 are flexible to mate with the charging socket 50. For example, the testing probes 250 may be flexed inward during loading through the end of the receptacle 52 and are then spread outward within the hollow receptacle 52 to press outward against the surfaces of the charging socket 50 to maintain a reliable electrical connection with the charging socket 50.

The testing sensor 200 is used to measure resistance in the charging socket 50 to monitor the health of the charging socket 50. For example, if the resistance measurement is low (for example, less than a threshold resistance) then the charging socket 50 is operating normally and is safe to use to charge the electric vehicle. However, if the resistance measurement is high (for example, above a threshold resistance) than the charging socket 50 is operating abnormally and may be unsafe to used to charge the electric vehicle or may be charging incorrectly and/or slowly. High resistance may lead to overheating and/or damage to the charging plug or the charging inlet of the electric vehicle. In an exemplary embodiment, the testing sensor 200 uses a four wire measuring technique to test for electrical impedance of the charging socket 50. The testing sensor 200 may use separate pairs of current-carrying and voltage-sensing electrodes to make accurate measurements. For example, one pair of wires may carry current to the charging socket 50 under test and the other pair of wires may measure the voltage drop through the charging socket 50. Separation of current and voltage electrodes may eliminate the lead and contact resistance from the measurement to provide precise measurement of low resistance values. In various embodiments, the testing sensor 200 may have a sensitivity of less than 0.001 Ohm.

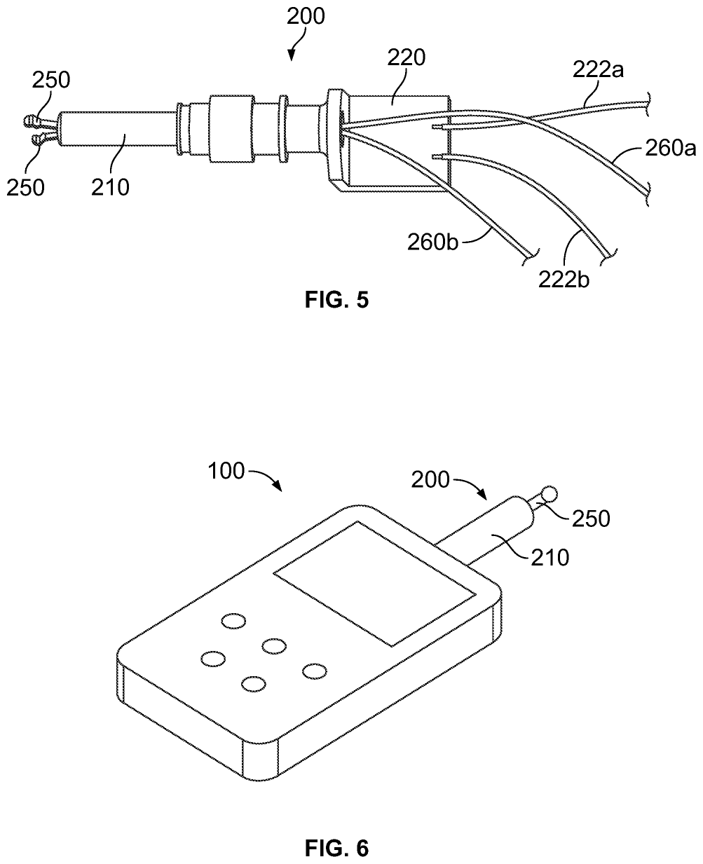

FIG. 5 is a perspective view of the testing sensor 200 in accordance with an exemplary embodiment. The testing sensor 200 includes a testing pin 210 and the testing probes 250 extending from the front end of the testing pin 210. The tab 220 is located at the opposite end of the testing pin 210. First and second wires 222a, 222b are connected to the tab 220, and are thus electrically coupled to the testing pin 210. The first wire 222a may be a current-carrying wire and the second wire 222b may be a voltage-sensing wire. Third and fourth wires 260 extend from the testing sensor 200. The third and fourth wires 260 are electrically connected to the corresponding testing probes 250. The third wire 260a may be a current-carrying wire and the fourth wire 260b may be a voltage-sensing wire. The four wires 222a, 222b, 260a, 260b may be electrically connected to the control panel 150 to measure the resistance of the charging socket 50.

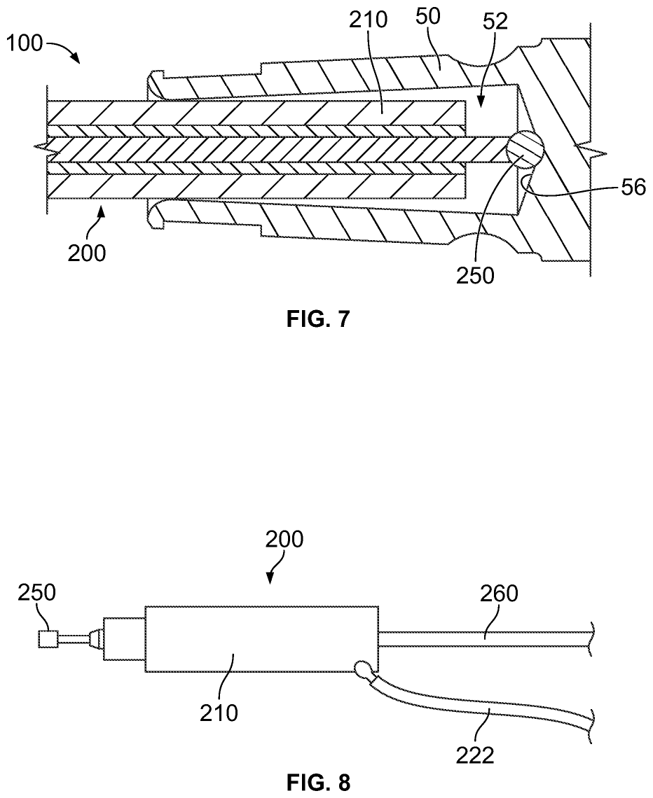

FIG. 6 illustrates the monitoring device 100 in accordance with an exemplary embodiment. FIG. 7 is a cross-sectional view of the monitoring device 100 testing the charging socket 50 in accordance with an exemplary embodiment. The monitoring device 100 shown in FIGS. 6 and 7 illustrate a two wire measuring device rather than the four wire measuring device shown in FIGS. 3 and 4. The testing sensor 200 includes the testing pin 210 and a single testing probe 250. Optionally, the testing probe 250 may include a Pogo pin configured to be spring biased against the inner end 56 of the receptacle 52 of the charging socket 50.

FIG. 8 is a perspective view of the testing sensor 200 shown in FIGS. 6 and 7 in accordance with an exemplary embodiment. The testing sensor 200 includes the testing pin 210 and the testing probe 250 extending from the front end of the testing pin 210. The tab 220 is located at the opposite end of the testing pin 210. The wire 222 is connected to the tab 220, and are thus electrically coupled to the testing pin 210. The wire 260 extends from the testing sensor 200 and is electrically connected to the testing probe 250. The wires 222, 260 may be electrically connected to the control panel 150 to measure the resistance of the charging socket 50.

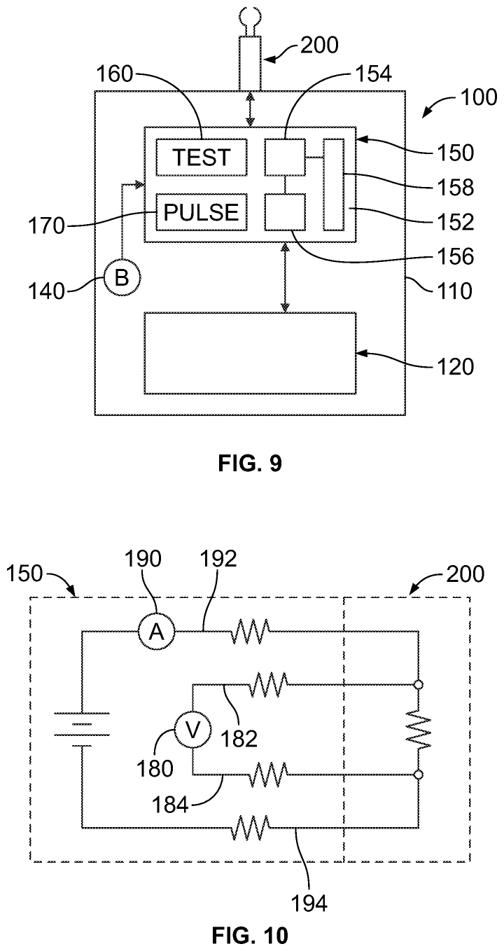

FIG. 9 is a schematic view of the monitoring device 100 in accordance with an exemplary embodiment. The monitoring device 100 includes the control panel 150 and the user interface 120 in the device housing 110. The control panel 150 may receive inputs from the user interface 120 and/or send output to the user interface 120. The monitoring device 100 includes the testing sensor 200 coupled to the control panel 150. In an exemplary embodiment, the monitoring device 100 includes a battery 140 coupled to the control panel 150. The battery 140 supplies power to the control panel 150 for running the health test of the charging socket 50. In an exemplary embodiment, the battery 140 is rechargeable.

The control panel 150 includes electrical components for controlling operation of the monitoring device 100. In an exemplary embodiment, the control panel 150 includes one or more circuit boards 152 having various circuits for connecting the electrical components. The battery 140 may be mounted to the circuit board 152 or may be connected to the circuit board 152 by one or more wires. The wires 222, 260 (shown in FIG. 5) may be terminated to various circuits of the circuit board 152. In an exemplary embodiment, the control panel 150 includes one or more processors 154 and one or more memories 156 mounted to the circuit board 152. The processor(s) 154 may receive signals from the testing sensor 200 to calculate or determine a resistance measurement for the charging socket 50. The processor 154 may compare the resistance measurement to data stored in the memory 156 to determine a health output for the charging socket 50. For example, the memory 156 may include a database of resistance measurements, such as resistance measurements for good charging sockets and bad charging sockets to compare the measured resistance to the database to determine the health of the charging socket under test (for example to determine if the charging socket 50 passes or fails the health test). The health output may be sent to the user interface 120 for display to the user. In an exemplary embodiment, the control panel 150 includes a communication module 158 to communicate data to the user interface 120 or to an external device separate from the monitoring device 100. The communication module 158 may be a wireless communication module.

In an exemplary embodiment, the control panel 150 may operate the monitoring device 100 in different modes. For example, the monitoring device 100 may be operated in a testing mode during normal testing. The control panel 150 includes a test module 160 for controlling the monitoring device 100 in the testing mode. For example, the test module 160 may include one or more routines for operating the control panel 150. For example, the test module 160 may control the current and/or the voltage supplied to the testing sensor 200 during the testing process. In an exemplary embodiment, the control panel 150 includes a pulse module 170 for controlling the monitoring device 100 in a pulsing mode. For example, the pulse module 170 may include one or more routines for operating the control panel 150. The pulse module 170 may control the current and/or the voltage supplied to the testing sensor 200 during the pulsing process. In the pulse mode, the monitoring device 100 may supply high current and/or high voltage for short periods of time, such as during a series of pulses to prepare the charging socket 50 for testing. The current and/or the voltage may be higher in the pulse mode and in the testing mode. The pulse mode may be used to send a pulse voltage to penetrate oxide layers on the charging socket 50, such as to remove the oxide layers prior to testing the charging socket 50. The control panel 150 may include a capacitor which is charged during or prior to operating in the pulse mode. The monitoring device 100 may be operated in other modes in various embodiments.

FIG. 10 is a schematic view of the monitoring device 100 in accordance with an exemplary embodiment. The monitoring device 100 is used to measure a resistance of the charging socket 50 using the testing sensor 200. FIG. 10 illustrates a Kelvin (4 wire) resistance measurement circuit for the monitoring device 100. The control panel 150 includes a voltmeter 180 and an ammeter 190. Pairs of current-carrying wires 192, 194 are connected to the ammeter 190 to carry current to the charging socket 50 under test. Pairs of voltage-sensing wires 182, 184 are connected to the voltmeter 180 to measure the voltage drop through the charging socket 50. The testing sensor 200 is used to accurately measure resistance in the charging socket 50 to monitor the health of the charging socket 50. The testing sensor 200 differentiates between a good connection and a bad connection, such as by comparing the measured resistance to a threshold resistance value and/or a database of known connections. As such, the monitoring device 100 can be used to determine if the charging socket 50 needs to be serviced or replaced.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112 (f), unless and until such claim limitations expressly use the phrase “means for” followed by a statement of function void of further structure.

What is claimed is:

1. A charging station health monitoring device for monitoring a health of a charging socket of a charging station, the charging station health monitoring device comprising:
a device housing having a user interface;
a control panel in the device housing, the control panel operably coupled to the user interface; and
a testing sensor coupled to the control panel, the testing sensor coupled to the control panel, the testing sensor including a testing pin, a testing probe, and an insulator between the testing pin and the testing probe, the testing pin including a pin interface, the testing probe including a probe interface, the probe interface spaced apart from the pin interface;
wherein the testing sensor is configured to be plugged into the charging socket such that the pin interface and the probe interface are configured to engage the charging socket at different testing locations to determine a resistance measurement for the charging socket.

2. The charging station health monitoring device of claim 1, wherein the testing probe is deflectable.

3. The charging station health monitoring device of claim 1, wherein the pin interface is a first distance from a central axis of the testing sensor and the probe interface is a second distance from the central axis, the second distance being greater than the first distance.

4. The charging station health monitoring device of claim 1, wherein the testing pin is cylindrical.

5. The charging station health monitoring device of claim 1, wherein the testing sensor is a four wire resistance sensor configured to determine a resistance measurement for the charging socket.

6. The charging station health monitoring device of claim 1, wherein the testing sensor extends from the device housing.

7. The charging station health monitoring device of claim 1, wherein the testing sensor is connected to the device housing by a cable.

8. The charging station health monitoring device of claim 1, wherein the testing pin is hollow, the testing probe extending through the hollow interior of the testing pin.

9. The charging station health monitoring device of claim 1, wherein the control panel receives the resistance measurement and sends an output to the user interface indicative of the health of the charging station.

10. The charging station health monitoring device of claim 9, wherein the control panel sends a passing output if the resistance measurement is below a threshold resistance and the control panel sends a fail output if the resistance measurement is above the threshold resistance.

11. The charging station health monitoring device of claim 1, wherein the control panel sends a pulse voltage to the testing sensor prior to sending a test voltage to the testing sensor, the pulse voltage being higher than the test voltage.

12. The charging station health monitoring device of claim 1, further comprising a battery in the device housing, the battery operably coupled to the control panel to operate the testing sensor.

13. The charging station health monitoring device of claim 1, wherein the testing probe is a first testing probe, the testing sensor including a second testing probe separate from the first testing probe and configured to engage the charging socket at a different testing location from the first testing probe.

14. The charging station health monitoring device of claim 13, wherein a first wire is connected to the first testing probe, a second wire is connected to the second testing probe, a third wire is connected to the testing pin, and a fourth wires connected to the testing pin.

15. A charging station health monitoring device for monitoring a health of a charging socket of a charging station, the charging station health monitoring device comprising:
a device housing having a user interface;
a control panel in the device housing, the control panel operably coupled to the user interface; and
a testing sensor coupled to the control panel, the testing sensor coupled to the control panel, the testing sensor including a four wire resistance probe configured to be plugged into the charging socket to interface with the charging socket at four points to determine a resistance measurement for the charging socket.

16. The charging station health monitoring device of claim 15, wherein the control panel receives the resistance measurement and sends an output to the user interface indicative of the health of the charging station, the control panel sending a passing output if the resistance measurement is below a threshold resistance and the control panel sending a fail output if the resistance measurement is above the threshold resistance.

17. The charging station health monitoring device of claim 15, wherein the control panel sends a pulse voltage to the testing sensor prior to sending a test voltage to the testing sensor, the pulse voltage being higher than the test voltage.

18. A method of monitoring health of a charging socket of a charging station, the method comprising:
providing a charging station health monitoring device including a device housing having a user interface, a control panel in the device housing operably coupled to the user interface, and a testing sensor coupled to the control panel;
plugging the testing sensor into the charging socket such that a pin interface of a testing pin of the testing sensor engages the charging socket at a first testing location and a probe interface of a testing probe of the testing socket engages the charging socket at a second testing location;
determining a resistance measurement for the charging socket using the testing pin and the testing probe; and
providing an output at the user interface based on the resistance measurement indicative of the health of the charging socket.

19. The method of claim 18, wherein said determining a resistance measurement includes performing a four wire resistance measurement.

20. The method of claim 18, further comprising sending a pulse voltage to the testing sensor prior to sending a test voltage to the testing sensor, the pulse voltage being higher than the test voltage.
